(19) United States
(12) Patent Application Publication
(10) Pub. No.: US 2006/0286801 A1
(43) Pub. Date: Dec. 21, 2006

(54) Process chamber assembly and apparatus for processing a substrate

(75) Inventor: Ho-Gon Kim, Suwon-Si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/448,727

(22) Filed: Jun. 8, 2006

(30) Foreign Application Priority Data
Jun. 16, 2005 (KR) 2005-52051

(51) Int. Cl. H01L 21/44; C23C 16/00

(52) U.S. Cl. 438/680; 118/719

(57) ABSTRACT

In a process chamber assembly and a processing apparatus for processing a substrate using, a process chamber assembly may include a process chamber including a body having a first contact face and a cover for covering the body having a second contact face, the second contact face of the cover seals the body at the first contact face thereof forming a buffer space therebetween, and at least one combining unit in fluid communication with the buffer space and configured to provide vacuum therein.

### CLAIM OF PRIORITY

A claim of priority is made under 35 USC § 119 to Korean Patent Application No. 2005-52051, filed on Jun. 16, 2005, the contents of which are herein incorporated by reference in their entirety.

### BACKGROUND

1. Field

Example embodiments of the present invention relate to a process chamber assembly and an apparatus for processing a substrate.

2. Description of the Related Art

Generally, a semiconductor device may be manufactured by various fabrication processes to form an electrical circuit on a semiconductor substrate, for example, a silicon substrate. Fabrication processes may include a deposition process to form a layer on a silicon substrate, a chemical mechanical polishing process to planarize a surface of the layer using a slurry, a photolithography process to form a photoresist pattern on the layer, an etching process to form a pattern having electrical characteristics using the photoresist pattern as an etching mask, an ion implantation process to implant ions onto designated regions of the silicon substrate, a cleaning process to remove contaminants from the silicon substrate, and/or an inspection process to inspect a surface of the silicon substrate having the layer and/or a pattern.

The deposition process, for example, may be classified into a physical vapor deposition (PVD) process and a chemical vapor deposition (CVD) process. The CVD process may be divided into an atmospheric pressure chemical vapor deposition (APCVD) process and a low-pressure chemical vapor deposition (LPCVD) process.

An APCVD process may be carried out under an atmospheric pressure (about 760 Torr). An LPCVD process may be performed under a relatively low pressure of no more than about 650 Torr, which is lower than atmospheric pressure, using a vacuum pump.

An APCVD apparatus has a relatively high deposition rate; and thus, the APCVD apparatus may be capable of effectively processing semiconductor substrates. However, when a layer has a thickness more than a given or predetermined thickness, an operation of the APCVD apparatus may be suspended. Accordingly, cleaning processes to remove byproducts, for example, powders in a process chamber of the APCVD apparatus, as well as the substrate, may be carried out.

Because the cleaning process is a manual process, any operation on an APCVD apparatus must be suspended during the cleaning process. Therefore, although the APCVD apparatus may be capable of processing a relatively large number of semiconductor substrates, efficiency of the APCVD apparatus may be reduced if the operation of the APCVD apparatus is suspended for a long period of time.

A process chamber of an LPCVD apparatus operates at a relatively low pressure. Thus, the LPCVD apparatus may be cleaned using a remote plasma cleaning apparatus that may be operated under a relatively low pressure. Therefore, after cleaning the process chamber, an LPCVD process may be immediately restarted with respect to a subsequent substrate or unit lot.

However, in an LPCVD process, a process chamber must be maintained under pressure. Thus, a process gas used during a deposition process must be exhausted external to the process chamber. As a result, the LPCVD apparatus has a relatively low deposition rate, thus reducing the efficiency of the LPCVD apparatus.

Further, a process chamber of an LPCVD apparatus may include an opened body and a cover for covering the opened body. In the LPCVD apparatus, when a pressure in the process chamber is increased no less than an atmospheric pressure (about 760 Torr) to enhance a deposition rate of a deposition material, a gap may be formed between the cover and the opened body causing a process gas leak through the gap.

### SUMMARY

Example embodiments of the present invention may provide a process chamber assembly that is capable of sealing a process chamber without changing an internal pressure of the process chamber.

In an example embodiment of the present invention, a process chamber assembly may include a process chamber including a body having a first contact face and a cover for covering the body having a second contact face, the second contact face of the cover seals the body at the first contact face thereof forming a buffer space therebetween, and at least one combining unit in fluid communication with the buffer space and configured to provide vacuum therein.

In an example embodiment of the present invention, a processing apparatus for processing a substrate may include a process chamber including a body having a first contact face and a cover for covering the body having a second contact face, the second contact face of the cover seals the body at the first contact face thereof forming a buffer space therebetween, at least one combining unit in fluid communication with the buffer space and configured to provide vacuum therein, and a gas-supplying unit configured to provide processing gas.

### BRIEF DESCRIPTION OF THE DRAWINGS

Example embodiments of the present invention will become more apparent with the detailed description of example embodiments with reference to the accompanying drawings, in which:

FIG. 1 is a cross sectional view illustrating a process chamber assembly in accordance with an example embodiment of the present invention;

FIG. 2 is a plan view illustrating a connection structure between a groove and a pump unit according to an example embodiment of the present invention;

FIG. 3 is a plan view illustrating a connection structure between a groove and a pump in accordance with another example embodiment of the present invention;

FIG. 4 is a plan view illustrating a connection structure between a groove and a pump in accordance with yet another example embodiment of the present invention;

FIG. 5 is a plan view illustrating a connection structure between a groove and a pump in accordance with still another example embodiment of the present invention;

FIG. 6 is a plan view illustrating a connection structure between a groove and a pump in accordance with another example embodiment of the present invention;

FIG. 7 is a cross sectional view illustrating a process chamber assembly in accordance with another example embodiment of the present invention; and

FIG. 8 is a cross sectional view illustrating an apparatus for processing a substrate in accordance with an example embodiment of the present invention.

### DESCRIPTION OF THE EXAMPLE EMBODIMENTS

Example embodiments of the present invention may be described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

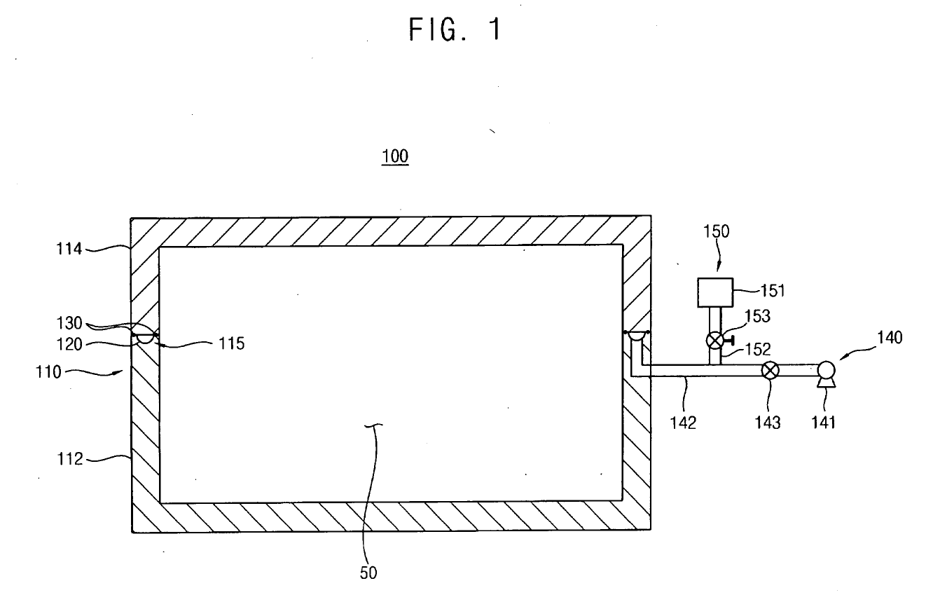

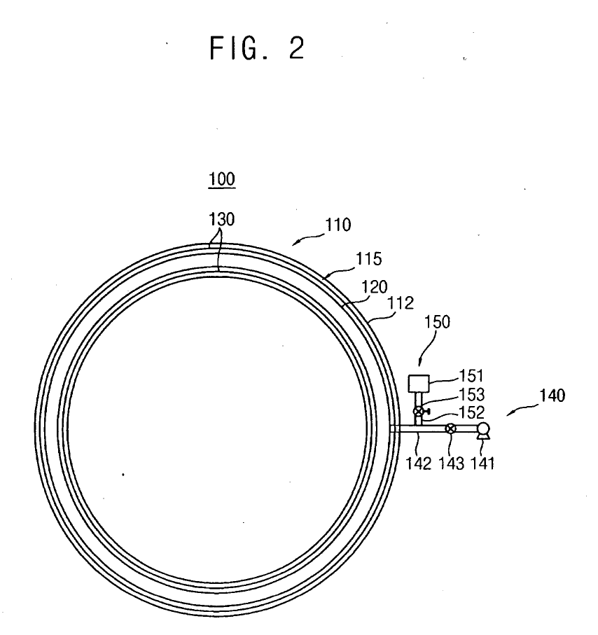

FIG. 1 is a cross sectional view illustrating a process chamber assembly in accordance with an example embodiment of the present invention, and FIG. 2 is a plan view illustrating a connection structure between a groove and a pump according to an example embodiment of the present invention.

Referring to FIGS. 1 and 2, a process chamber assembly 100 may include a process chamber 110, a contact portion 115, a sealing member 130, a combining unit 140, and/or a separating unit 150.

The process chamber 110 may have sufficient processing space 50 to process a substrate (not shown). The process chamber 110 may be a cylindrical shape (FIG. 2). The process chamber 110 may include a body 112 having an opened portion (processing space), and a cover 114 to cover the body 112.

The contact portion 115 may be interposed between the body 112 and the cover 114. A groove 120 may be formed along a first contact face of the body 112 that makes contact with the cover 114. The groove 120, for example, may have a circular shape as shown in FIG. 2.

A buffer space between the body 112 and the cover 114 may be defined by the body 112 having the groove 120 and the cover 114. Alternatively, the groove 120 may be formed along a second contact face of the cover 114 that makes contact with the first contact face of the body 112. Further, the groove 120 may be formed along both contact faces, a first groove may be formed along the first contact face of the body 112, and a second groove corresponding to the first groove may be formed along the second contact face that makes contact with the first contact face.

The sealing members 130, to hermetically seal the buffer space, may be placed in the groove 120. The sealing members 130 may include one or more O-rings (not shown), each O-ring having diameters different from each other. Further, the sealing members 130 may be arranged at both sides of the groove 120.

The combining unit 140 may provide vacuum to the buffer space. In other words, the combining unit 140 may seal the process chamber assembly 100 with the vacuum. In an example embodiment of the present invention, the combining unit 140 may provide vacuum into the buffer space, which has a lower pressure than an internal pressure of the process chamber assembly 100.

The combining unit 140 may include a pump unit 141, a first line 142, and a valve 143. The pump unit 141 may be used to provide vacuum into the buffer space. The first line 142 may connect the pump unit 141 to the groove 120. In other words, the first line 142 may connect the pump unit 141 to the buffer space. The valve 143 may open and close the first line 142.

The separating unit 150 may provide gas into the buffer space. The separating unit 150 may assist in opening the process chamber 110. The separating unit 150 may include a gas reservoir 151, a second line 152, and a needle valve 153. The gas reservoir 151 may provide gas into the buffer space. Examples of gases provided to the buffer space may include dry air, inert gas, etc., which may be used alone or in a mixture thereof. The second line 152 may connect the gas reservoir 151 to the first line 142. The second line 152 may be connected to the first line 142 between the groove 120 and the valve 143. The needle valve 153 may adjust flow of gas passing through the second line 152. Alternatively, the needle valve 153 may open or close the second line 152.

In an example embodiment of the present invention, the second line 152 may be connected between the gas reservoir 151 and the first line 142. In another example embodiment of the present invention, the second line 152 may directly connect the gas reservoir 151 to the groove 120. That is, the second line 152 may directly connect the gas reservoir 151 to the buffer space.

The body 112 and the cover 114 of the process chamber assembly 100 may be combined using vacuum to seal the process chamber 110. Thus, the internal pressure of the process chamber 110 may be varied.

Hereinafter, an operation of a process chamber assembly 100 will be illustrated in detail.

To seal a process chamber 110, a body 112 may be covered with a cover 114 to form the buffer space between a first contact face of the body 112 and a second contact face of the cover 114. A separating unit 150 may close a needle valve 153, and a combining unit 140 may open the valve 143. A pump 141 may provide vacuum into the buffer space. For example, the vacuum in the buffer space may be about 1 mTorr to about 10 mTorr. Thus, the body 112 and the cover 114 may be tightly sealed by the vacuum. When the body 112 is combined with the cover 114 through the vacuum, the internal pressure of the process chamber 110 may be varied. For example, the internal pressure in the process chamber 110 may be the same as atmospheric pressure, about 760 Torr. Alternatively, the internal pressure in the process chamber 110 may be no less than about 760 Torr. Alternatively, the internal pressure in the process chamber 110 may be no more than about 650 Torr.

To open the process chamber 110, the valve 143 may be closed, and then the needle valve 153 may be gradually opened. Thus, gas stored in a gas reservoir 151 may be gradually supplied into the buffer space through the needle valve 153. The gas may be supplied to the buffer space until a pressure of the buffer space is substantially equal to or no more than the atmospheric pressure (about 760 Torr). For example, when the pressure of the buffer space is substantially identical to the atmospheric pressure, the cover 114 may be easily separated from the body 112. Thus, the internal pressure of the process chamber 110 may also be substantially similar to the atmospheric pressure.

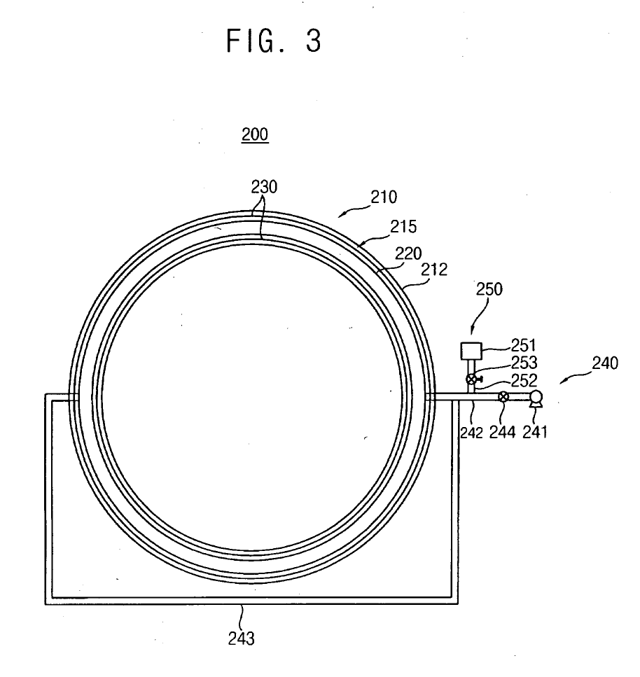

FIG. 3 is a plan view illustrating a connection structure between a groove and a pump in accordance with an example embodiment of the present invention.

Referring to FIG. 3, a process chamber assembly 200 includes a process chamber 210, a contact portion 215, a sealing member 230, a combining unit 240, and a separating unit 250. The process chamber assembly 200 as shown in FIG. 3 may include elements substantially similar to those of the process chamber assembly 100 in FIGS. 1 and 2 except for the combining unit 240. Thus, further detail illustrations of similar elements will be omitted.

The combining unit 240 may provide vacuum in a buffer space formed between a body 212 and a cover (not shown). The combining unit 240 may assist in sealing the process chamber 210 with vacuum. In an example embodiment of the present invention, the combining unit 240 may provide vacuum into the buffer space.

The combining unit 240 may include a pump unit 241, a first line 242, a second line 243, and a valve 244. The pump unit 241 may provide vacuum to the buffer space. The first line 242 connects the pump unit 241 to a first position of a groove 220. In other words, the first line 242 connects the pump unit 241 to a first position of the buffer space.

The second line 243 may connect the first line 242 to a second position opposite to the first end of the groove 220. In other words, the second line 243 connects the first line 242 to a second end of the buffer space. In an example embodiment of the present invention, the second line 243 may be connected to the first line 242 between the groove 220 and the valve 244.

The valve 244 may be installed in the first line 242 to close or open the first line 242.

The pump unit 241 may uniformly exhaust air from the buffer space to the exterior of the buffer space through the first line 242 and the second line 243.

In an example embodiment of the present invention, the pump unit 241 and the groove 220 may commonly connected by the first and second lines 242 and 243. In another example embodiment of the present invention, the pump unit 241 may be connected to the groove 220 by at least three lines. The three lines may be spaced apart from each other by substantially same intervals.

The cover (not shown) may be combined with the body 212 to close the process chamber 210 under vacuum. When the body 212 is combined with the cover 214 under vacuum, an internal pressure of the process chamber 210 may be varied.

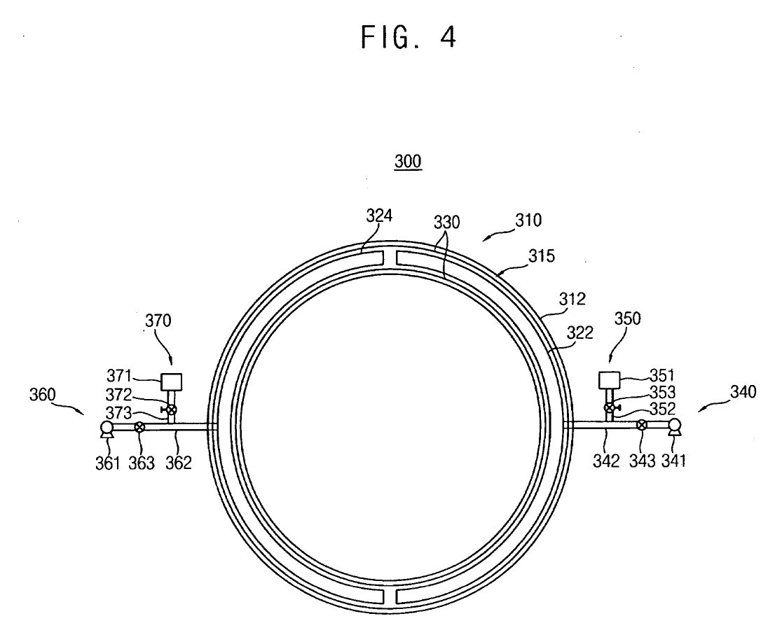

FIG. 4 is a plan view illustrating a connection structure between a groove and a pump in accordance with another example embodiment of the present invention.

Referring to FIG. 4, a chamber process assembly 300 may include a process chamber 310, a contact portion 315, a sealing member 330, a first combining unit 340, a first separating unit 350, a second combining unit 360, and a second separating unit 370. The process chamber assembly 300 may include elements substantially similar to those of the process chamber assembly 100 illustrated in FIGS. 1 and 2 except for a shape of a groove formed in the process chamber 310, and the addition of the second combining unit 360 and the second separating unit 370. Thus, any further illustrations of similar elements will be omitted.

A first contact face of the body 312 that makes contact with a second contact face of a cover (not shown) may include a first groove 322 and a second groove 324. Each of the first groove 322 and the second groove 324 may have a semi-circular shape from a plan view and may be formed along the first contact face. Thus, when each end of the first groove 322 and each end of the second groove 324 meet with each other, the first and second grooves 322 and 324 have a circular shape from a plan view. In an example embodiment of the present invention, the first groove 322 and the second groove 324 may have equal semicircular shape formed on the same concentric plane on the first contact face of the body 310.

The first combining unit 340 and the first separating unit 350 may be connected to the first groove 322. The second combining unit 360 and the second separating unit 370 may be connected to the second groove 324. Connection structures between the first groove 322, the first combining unit 340, and the first separating unit 350, and connection structures between the second groove 324, the second combining unit 360, and the second separating unit 370 may be substantially similar to those between the groove 120, the combining unit 140, and the separating unit 150 as illustrated in FIGS. 1 and 2.

The cover (not shown) may be combined with the body 312 under vacuum to seal the process chamber 310. When the body 312 is combined with the cover 314, the internal pressure of the chamber 310 may be varied.

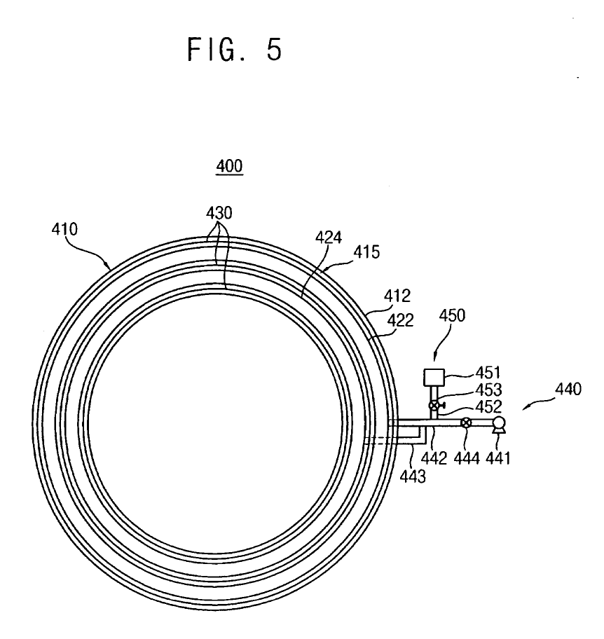

FIG. 5 is a plan view illustrating a connection structure between a structure of a groove and a pump in accordance with a still another example embodiment of the present invention.

Referring to FIG. 5, a process chamber assembly 400 may include a process chamber 410, a contact portion 415, a sealing member 430, a combining unit 440, and a separating unit 450.

The process chamber 410 may include a body 412 and a cover (not shown) for covering the body 412. The body 412 may have a first contact face that makes contact with a second contact face of the cover. The first contact face of the body 412 may have a first groove 422 and a second groove 424, thereby forming first and second buffer spaces (not shown), respectively. Each of the first groove 422 and the second groove 424 may have an annular shape. The first and second grooves 422 and 424 may be arranged in a concentric circular pattern on the first contact face. The first groove 422 may have a larger diameter than the second groove 424. Therefore, the second groove 424 may be inside the first groove.

The body 412 having the first groove 422 and the second groove 424 may be covered with the cover so that the first buffer space (not shown) and the second buffer space (not shown) may be formed between the body 412 and the cover.

The sealing member 430 may be placed on the contact portion 415. For example, the sealing member 430 may include three O-rings (not shown), each of the O-rings having different diameters from each other. A first O-ring (not shown) may be placed on an outer portion of the second groove 422, a second O-ring (not shown) may be positioned on an inner portion of the third groove 424, and a third O-ring (not shown) may be interposed between the second groove 422 and the third groove 424. The sealing member 430 may seal the first buffer space and the second buffer space.

The combining unit 440 may include a pump 441, a first line 442, a second line 443, and a valve 444. The pump 441 may provide vacuum into both the first and second buffer spaces.

The first line 442 may connect the pump 441 to the second groove 422. In other words, the first line 442 may connect the pump 441 to the first buffer space. The second line 443 may couple the first line 442 to the third groove 424. In other words, the second line 443 couples the first line 442 to the second buffer space. The second line 443 may be connected to the first line 442 between the second groove 422 and the valve 444.

The valve 444 may be installed in the first line 442. The valve 444 may open/close the first line 442 and/or the second line 443.

In an example embodiment of the present invention, the separating unit 450 may be substantially similar to the separating unit 150 described with reference to FIGS. 1 and 2. Thus, any further illustrations of the separating unit 450 will be omitted.

The cover (not shown) may be combined with the body 412 under vacuum to close the process chamber 410. When the body 412 is combined with the cover 414, an internal pressure of the process chamber 410 may be varied.

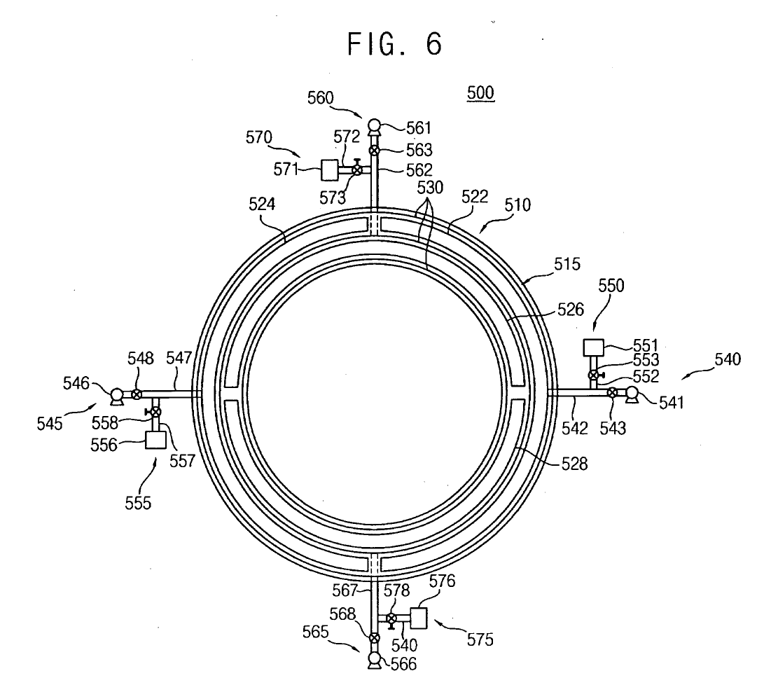

FIG. 6 is a plan view illustrating a connection structure between a groove and a pump in accordance with yet still another example embodiment of the present invention.

Referring to FIG. 6, a process chamber assembly 500 may include a process chamber 510, a contact portion 515, a sealing member 530, a first combining unit 540, a first separating unit 550, a second combining unit 545, a second separating unit 555, a third combining unit 560, a third separating unit 570, a fourth combining unit 565, and a fourth separating unit 575.

The process chamber 510 may have a body 512 and a cover (not shown) for covering the body 512. The body 512 may have a first contact face that makes contact with a second contact face of the cover (not shown). Along the first contact face of the body 510 there may be formed a first groove 522, a second groove 524, a third groove 526, and a fourth groove 528. The first, second, third, and fourth grooves 522, 524, 526 and 528 may have a semi-circular shape. Each ends of the first and second grooves 522, 524 may face each other. In other words, the second and third grooves 522, 524 are on the same first concentric plane on the first contact face of the body 510. Each ends of the third and fourth grooves 526, 528 may face each other. In other words, the third and fourth grooves 526, 528 are on the same second concentric plane on the first contact face of the body 510. Therefore, in an example embodiment of the present invention the first and second grooves 522, 524 are formed on a different concentric plan than third and fourth grooves 526, 528. In other words, the third and fourth grooves 526, 528 are inside the first and second grooves 522, 524.

First separated portions between the first and second grooves 522 and 524 may be arranged at a position different from second separated portions between the third and fourth grooves 526 and 528. Particularly, the first separated portions may be arranged substantially perpendicular to the second separated portions with respect to a center point of the body 512.

The sealing member 530 may be placed on the contact portion 515. The sealing member 530 may include three O-rings (not shown), each of the O-rings may have diameters different from each other. A first O-ring (not shown) may be placed at an outer portion of the first and second grooves 522 and 524. A second O-ring (not shown) may be placed at an inner portion of the third and fourth grooves 526 and 528. A third O-ring (not shown) may be interposed between the first and second O-rings.

The first combining unit 540, the first separating unit 550, the second combining unit 545, the second separating unit 555, the third combining unit 560, the third separating unit 570, the fourth combining unit 565, and the fourth combining unit 575 may be substantially similar to the combining unit 140 and the separating unit 150 as described with reference to FIGS. 1 and 2. Further detail explanation of similar elements will be omitted.

In an example embodiment of the present invention, the first separating unit 550 may be connected to the first groove 522. The second combining unit 545 and the second separating unit 555 may be connected to the second groove 524. Further, the third combining unit 560 and the third separating unit 570 may be connected to the third groove 526. The fourth combining unit 565 and the fourth separating unit 575 may be connected to the fourth groove 528.

The cover (not shown) may be combined with the body 512 under vacuum to close the process chamber 510. When the body 512 is combined with the cover with the vacuum, the internal pressure of the process chamber 510 may be varied.

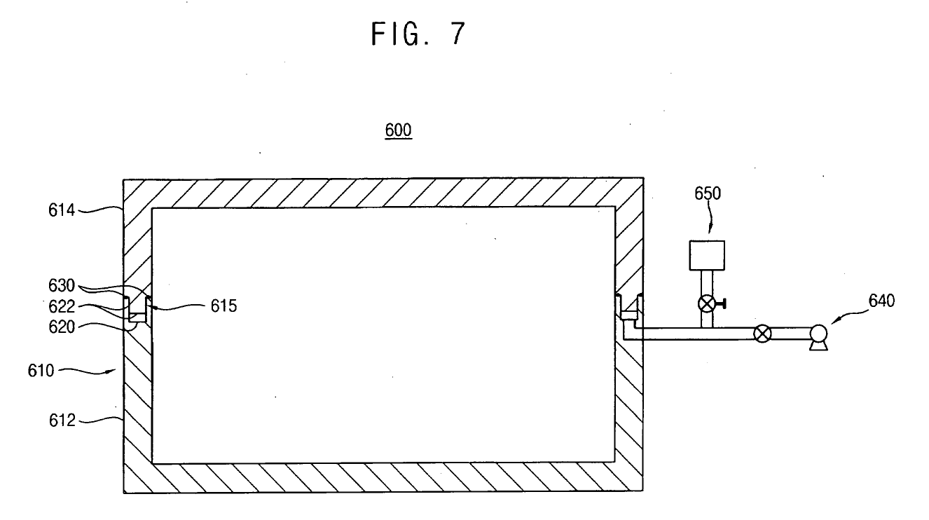

FIG. 7 is a cross sectional view illustrating a process chamber assembly in accordance with another example embodiment of the present invention.

Referring to FIG. 7, a process chamber assembly 600 may include a process chamber 610, a contact portion 615, a sealing member 630, a combining unit 640, and a separating unit 650.

The process chamber 610 may have a cylindrical shape. The process chamber 610 may include an opened body 612 and a cover 614 for covering the opened body 612. The body 612 may have a first contact face that makes contact with the cover 614 and the cover 614 has a second contact face that makes contact with the first contact face of the body 612. The contact portion 615 may be formed between the first contact face and the second contact face. A groove 620 may be formed along the first contact face of the body 612. The groove 620 may have an annular shape from a plan view.

A protrusion 622 is formed along the second contact face of the cover 614. The protrusion 622 may be opposite to the groove 620. The protrusion 622 may also have an annular shape corresponding to the groove 620. A height of the protrusion 622 measured from the second contact face of the cover 614 may be smaller than a depth of the groove 620 measured from a bottom face of the groove 620. Thus, buffer space may be formed between the protrusion 622 and the groove 620.

In an example embodiment of the present invention, the groove 620 may be formed on the first contact face of the body 612. The protrusion 622 may be formed on the second contact face of the cover 614. In an example embodiment of the present invention, a groove having a desired depth may be formed on the second contact face of the cover 614. A protrusion having a height that is smaller than the depth of the groove may be formed on the first contact face of the body 612.

The sealing member 630, the combining unit 640, and the separating unit 650 may be the similar to the sealing member 130, the combining unit 140, and the separating unit 150 described with reference to FIGS. 1 and 2. Thus, any further illustrations of the sealing member 630, the combining unit 650, and the separating unit 650 will be omitted.

Further, the process chamber assembly 600 may have a structure substantially similarly to those of the process chamber assembles previously disclosed above.

The cover 614 may be combined with the body 612 under vacuum to seal the process chamber 610. When the body 612 is combined with the cover 614 under vacuum, the internal pressure of the chamber 610 may be varied.

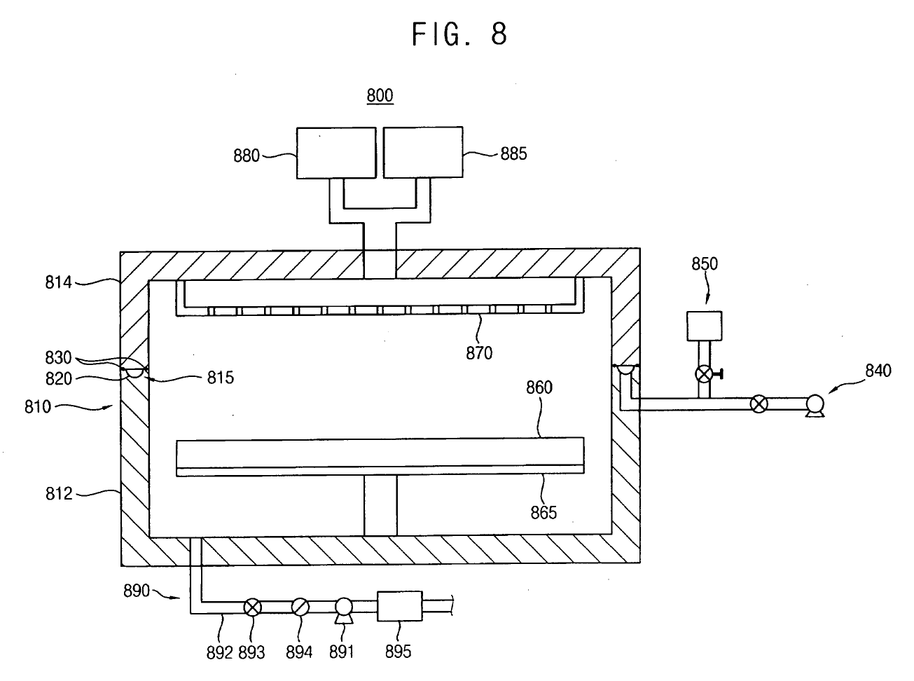

FIG. 8 is a cross sectional view illustrating a processing apparatus having a process chamber assembly configured to process a substrate.

Referring to FIG. 8, a processing apparatus 800 may include a process chamber 810, a contact portion 815, a sealing member 830, a combining unit 840, a separating unit 850, a suscepter 860, a heater 865, a showerhead 870, a gas-supplying unit 880, a cleaning unit 885, and an exhaust unit 890.

The process chamber 810, the contact portion 815, the sealing member 830, the combining unit 840, and the separating unit 850 may be substantially similar to elements described with reference to FIGS. 1 and 2. Thus, any further illustrations of the similar elements will be omitted.

Further, the process chamber 810, the contact portion 815, the sealing member 830, the combining unit 840, and the separating unit 850 may be replaced with a with any one of a process chamber, a contact portion, a sealing member, a combining unit, and a separating unit disclosed above.

The suscepter 860 may be arranged in a lower portion of the process chamber 810. The suscepter 860 may be positioned in a lower portion of the body 812. The suscepter 860 may be used to support the substrate.

The heater 865 may be integrally formed with the suscepter 860 at a lower portion of the suscepter 860. The heater 865 may uniformly heat the suscepter 860 so that a substrate on the suscepter 860 is uniformly heated.

The showerhead 870 may be placed in an upper portion of the process chamber 810. For example, the showerhead 870 may be arranged on an inner face of the cover 814. The showerhead 870 may uniformly distributes gas into the process chamber 810.

The gas-supplying unit 880 may be connected to the upper portion of the process chamber 810. In particular, the gas-supplying unit 880 may be connected to an upper face of the cover 814. The gas-supplying unit 880 may provide the showerhead 870 with a processing gas for processing the substrate that is supported by the suscepter 860. The processing gas may be uniformly provided into the process chamber 810 through the showerhead 870. Examples of the processing gas may include a deposition gas, an etching gas, etc.

The cleaning unit 885 may be connected to the upper portion of the process chamber 810. The cleaning unit 885 may be connected to the upper face of the cover 814. The cleaning unit 885 may provide a cleaning gas into the process chamber 810 for cleaning the process chamber 810. The cleaning gas may remove byproducts generated during the processing of substrates, and which may be attached to inner walls of the process chamber 810.

The cleaning unit 885 may further include a remote plasma generating unit (not shown) that excites the cleaning gas to convert the cleaning gas into plasma. Since the plasma may be applied into the process chamber 810, cleaning efficiency of the process chamber 810 may be improved.

The exhaust unit 890 may be connected to a lower portion of the process chamber 810, for example, to a lower portion of the container 812. The exhaust units may exhaust byproducts or un-reacted gases that may be generated during a substrate treating process or the above cleaning process out of the chamber 810.

The exhaust unit 890 may include a vacuum pump 891, a vacuum line 892, a gate valve 893, a throttle valve 894, and a gas scrubber 895.

The vacuum pump 891 may provide the process chamber 810 with vacuum. In addition, the vacuum pump 891 under vacuum may also exhaust byproducts that may be generated during a deposition process, an etching process, and a cleaning process, and any unreacted gases. The vacuum line 892 may be in fluid communication with the process chamber 810 and the vacuum pump 891. The vacuum pump 891 may open/close the gate valve 893. The throttle valve 894 may be installed in the vacuum line 892 to adjust the vacuum of the process chamber 810. The gas scrubber 895 may be installed in the vacuum pump 891. The gas scrubber 895 may purify toxic substances or harmful byproducts and/or unreacted gas.

Since the body 812 and the cover 814 of a processing apparatus 800 are sealed by vacuum, the process chamber 810 may be tightly closed. Thus, during a deposition process, an internal pressure of the process chamber 810 may be varied within a range of no less than the vacuum pressure of buffer space between the body 812 and the cover 814. Therefore, during a deposition process, the internal pressure of the process chamber 180 may be maintained at an atmospheric pressure to improve deposition rates. Further, during a cleaning process for cleaning the process chamber 810, internal pressure of the process chamber 810 may be maintained relatively low to improve cleaning efficiency.

Hereinafter, a deposition process operation using an apparatus for processing a substrate according to example embodiments of the present invention will be described.

A combining unit 840 may provide vacuum into buffer space that may be formed by a contact portion 815 to seal a process chamber 810. For example, an internal pressure of the buffer space may be within a range of about 1 mTorr to about 10 mTorr. The internal pressure of the chamber 810 may be maintained at an atmospheric pressure using a vacuum pump 891 and a throttle valve 894 of a separating unit 890.

A substrate may be loaded onto a suscepter 860 through a door. The substrate may be heated using a heater 865. Processing gas may be provided into the process chamber 810 to form a layer on the substrate. In an example embodiment of the present invention, a deposition rate of the layer may be relatively high because a deposition process for forming the layer on the substrate may be carried out under atmospheric pressure.

When the deposition process is completed, an exhaust unit 890 may externally exhaust byproducts that may have generated during the deposition process and any unreacted gases.

After performing the deposition process in the process chamber 810 for a desired time, a cleaning process for cleaning the byproducts attached on the inside walls of the chamber 810, which may have generated during the deposition process, is carried out.

To perform the cleaning process, an inner space of the process chamber 810 may be maintained under a low pressure using the exhaust unit 890. The cleaning unit 885 may provide plasma converted from the cleaning gas into the chamber 810. Thus, the byproducts attached on the inside wall of the chamber 810 are efficiently removed for a short time.

In example embodiments of the present invention, since a deposition process may be carried out under atmospheric pressure, deposition rates may be improved to process many substrates. Further, since a cleaning process may be carried out under a relatively low pressure, plasma may be used in the cleaning process so that the cleaning process may be rapidly and efficiently performed. As a result, processing efficiency of the processing apparatus may be improved.

The foregoing is illustrative of example embodiments of the present invention and is not to be construed as limiting thereof. Although several example embodiments of the present invention have been described, those skilled in the art will readily appreciate that many modifications may be possible without materially departing from the novel teachings and aspects of example embodiments of the present invention. Accordingly, all such modifications are intended to be included within the scope of present invention. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the example embodiments disclosed, and that modifications to the disclosed example embodiments, as well as other embodiments, are intended to be included within the scope of the present application.

What is claimed is:

1. A process chamber assembly comprising:
a process chamber including a body having a first contact face; and
a cover having a second contact face, the second contact face of the cover sealing the body at the first contact face and forming a first buffer space therebetween; and
at least one combining unit in fluid communication with the first buffer space and configured to provide vacuum therein.

2. The assembly of claim 1, wherein the first contact face of the body includes a first groove to provide the first buffer space.

3. The assembly of claim 1, wherein the second contact face of the cover includes a second groove to provide the first buffer space.

4. The assembly of claim 1, wherein the first contact face of the body includes a first groove and the second contact face of the cover includes a second groove to provide the first buffer space.

5. The assembly of claim 2, wherein the second contact face of the cover includes a protrusion, the protrusion protruding into the first groove when the second contact face of the cover seals the body at the first contact face thereof, and a height of the protrusion being smaller than a depth of the first groove.

6. The assembly of claim 3, wherein the first contact face of the body includes protrusion, the protrusion protruding into the first groove when the second contact face of the cover seals the body at the first contact face thereof, and a height of the protrusion being smaller than a depth of the first groove.

7. The assembly of claim 2, wherein the first contact face of the body further includes a third groove to provide for a second buffer space.

8. The assembly of claim 7, wherein the first and third grooves are continuous concentric circles, and are formed in two different concentric planes.

9. The assembly of claim 7, wherein the first and third grooves are semi-circular, disconnected, and provided in a same concentric plane.

10. The assembly of claim 9, wherein each of the first and second grooves is in fluid communication with the at least one combining unit.

11. The assembly of claim 7, wherein the first contact face of the body further includes a fourth groove and a fifth groove to provide a third buffer space and a fourth buffer space, respectively.

12. The assembly of claim 1, wherein each of the first, second, fourth, and fifth grooves is in fluid communication with the at least one combining unit.

13. The assembly of claim 1, further including a sealing member interposed between the first contact face of the body and the second contact face of the cover, the sealing member providing hermetic sealing between the body and cover.

14. The assembly of claim 1, wherein the at least one combining unit includes:
a pump unit configured to provide vacuum into the first buffer space;
a first line configured to connect the pump unit to the first buffer space; and
a valve configured to open and close the first line.

15. The assembly of claim 8, wherein the at least one combining unit includes:
a pump unit configured to provide vacuum into the first buffer space;
a first line configured to connect the pump unit to the first buffer space;
a second line connected to the first line on one end and connected to the second buffer space on the other end; and
a valve configured to open and close the first line.

16. The assembly of claim 14, further including a separating unit configured to separate the cover from the body by providing a gas between the first and second contact faces.

17. The assembly of claim 14, wherein the at least one combining unit further includes a second line, the second line connected to the first line on one end and connected to the second buffer space opposite to a connection point of the first line and the second buffer space on the other end.

18. A processing apparatus for processing a substrate, comprising:
the process chamber assembly of claim 1; and
a gas-supplying unit configured to provide processing gas.

19. The apparatus of claim 19, further including a cleaning unit connected to the process chamber and configured to clean the process chamber.

20. The apparatus of claim 19, further including a separating unit configured to separate the cover from the body by providing a gas between the first and second contact faces.
